(19) United States
(12) Patent Application Publication
(10) Pub. No.: US 2026/0255906 A1
(43) Pub. Date: Aug. 27, 2026

(54) TOOL AND METHOD FOR CLEANSING RESIDUES WITHIN A DIE OR SUBSTRATE GAP

(71) Applicant: Taiwan Semiconductor Manufacturing Co., Ltd., Hsinchu (TW)

(72) Inventors: Wen-Chang KUO, Hsinchu (TW); Yao-Chou TSAI, Hsinchu (TW)

(73) Assignee: Taiwan Semiconductor Manufacturing Co., Ltd., Hsinchu (TW)

(21) Appl. No.: 19/060,225

(22) Filed: Feb. 21, 2025

(51) Int. Cl. H01L 21/67; H01L 21/02; H01L 21/687

(52) U.S. Cl. CPC H10P 72/0404; H10P 70/27; H10P 72/7618

(57) ABSTRACT

The present disclosure is directed to respective embodiments of a flowhead including a gasket plate. A gasket positioned on the gasket plate. The gasket includes a first gasket portion of a first material, and a second gasket portion of a second material. The second gasket portion is coupled to the first gasket portion. A fluid hole extending through the gasket plate and into and through the first gasket portion. A fluid pathway is defined and delimited by the first gasket portion and the second gasket portion, and the fluid pathway extends into the second gasket portion to the first gasket portion. A fluid line is in fluid communication with the fluid hole, and the fluid line is configured, in operation, introduce one or more fluids into the fluid hole. The present disclosure is directed to methods of utilizing the flowhead.

### BACKGROUND

While manufacturing semiconductor packages one or more semiconductor die are coupled to a substrate utilizing a flux material or a temporary material that is later removed. For example, a semiconductor die is coupled to a substrate by a flux material in which solder balls are present. The flux material is then removed by introducing multiple fluids to the flux by ejecting the multiple fluids in succession from multiple nozzles that are moved into and out of a processing chamber. Each respective nozzle of the multiple nozzles ejects a specific fluid (i.e., a solvent, an ultra-pure water (UPW), a clean dry air (CDA), or some other similar or like type of fluid utilized within the semiconductor manufacturing industry). The flux material is deteriorated or removed by the introduction of these multiple fluids in succession between the die and the substrate. As multiple nozzles are utilized, the multiple nozzles have to be moved into and out of the processing chamber to introduce the multiple fluids in succession. When ejecting these respective fluids from these respective nozzles of the multiple nozzles, a cover is generally pre-positioned in advance to control a flow of the respective fluids being ejected from these respective nozzles when deteriorating and removing the flux material between the die and the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a system including a nozzle configured to, in operation, introduce a fluid at a region between a die and a substrate.

FIG. 1B is a cross-sectional side view of the system including the nozzle configured to, in operation, introduce the fluid at the region between the die and the substrate taken along line A-A as shown in FIG. 1A.

FIG. 2A is a perspective view of a flowhead, in accordance with some embodiments.

FIG. 2B is a cross-sectional, side view of the flowhead taken along line B-B as shown in FIG. 2A, in accordance with some embodiments.

FIG. 2C is a cross-sectional, side view of the flowhead taken along line C-C as shown in FIG. 2A, in accordance with some embodiments.

FIG. 2D is a bottom side view of the flowhead as shown in FIG. 2A, in accordance with some embodiments.

FIG. 3A is a perspective view of a system for removing a flux material between a die and a substrate, in accordance with some embodiments.

FIG. 3B is a cross-sectional view taken along line D-D of the system for removing a flux material between a die and a substrate as shown in FIG. 3A, in accordance with some embodiments.

FIG. 3C is a cross-sectional top down view of the system for removing the flux material between the die and the substrate taken along line E-E as shown in FIG. 3B, in accordance with some embodiments.

FIG. 4 is a cross-sectional top down view of the system for removing the flux material between the die and the substrate taken along line E-E as shown in FIG. 3B, in accordance with some embodiments.

FIG. 5 is a cross-sectional top down view of the system for removing the flux material between the die and the substrate taken along line E-E as shown in FIG. 3B, in accordance with some embodiments.

FIG. 6 is a cross-sectional top down view of the system for removing the flux material between the die and the substrate taken along line E-E as shown in FIG. 3B, in accordance with some embodiments.

FIG. 7 is a cross-sectional top down view of the system for removing the flux material between the die and the substrate taken along line E-E as shown in FIG. 3B, in accordance with some embodiments.

FIG. 8 is a cross-sectional top down view of a system including an alternative of a flowhead for removing a flux material between a die and a substrate, in accordance with some embodiments.

FIG. 9 is a cross-sectional top down view of a system including an alternative of a flowhead for removing a flux material between a die and a substrate, in accordance with some embodiments.

FIG. 10 is a cross-sectional side view of a system for removing a flux material between a die and a substrate, in accordance with some embodiments.

FIG. 11 is a flowchart of a method of removing a flux material between a substrate and a die with a flowhead, in accordance with some embodiments.

FIG. 12 is a flow diagram of respective steps of the flowchart of the method of removing the flux material between the substrate and the die with the flowhead as shown in FIG. 11, in accordance with some embodiments.

FIG. 13 is a schematic diagram of one or more respective fluid sources in fluid communication with a flowhead, in accordance with some embodiments.

FIG. 14A is a perspective view of a flowhead, in accordance with some embodiments.

FIG. 14B is a cross-sectional, side view of a flowhead taken along line F-F as shown in FIG. 14A, in accordance with some embodiments.

FIG. 14C is a cross-sectional, side view of the flowhead taken along line G-G as shown in FIG. 14A, in accordance with some embodiments.

FIG. 14D is a bottom side view of the flowhead as shown in FIG. 14A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

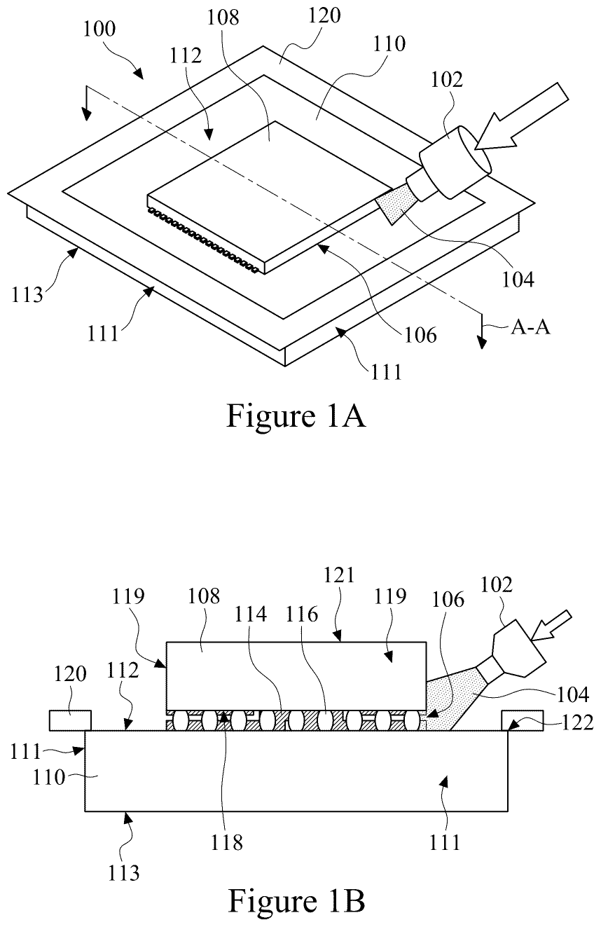

FIG. 1A is a perspective view of a system 100 including a nozzle 102 configured to, in operation, introduce a fluid 104 at a region 106 between a die 108 and a substrate 110. FIG. 1B is a cross-sectional side view of the system 100 including the nozzle 102 configured to, in operation, introduce the fluid 104 at the region 106 between the die 108 and the substrate 110.

The die 108 is coupled to a first surface 112 of the substrate 110 by a flux material 114 and one or more solder balls 116. The substrate includes a plurality of sidewall surfaces 111 that are transverse to the surface 112, and a second surface 113 that is opposite to the first surface 112. The plurality of sidewall surfaces 111 extend from the first surface 112 to the second surface 113. The die 108 further includes a plurality of sidewall surfaces 119 that are transverse to the surface 118 and extend from the surface 118 to another surface 121 of the die 108 opposite to the surface 118 of the die 108.

The flux material 114 is a temporary material that is utilized to assist in coupling the die 108 to the surface 112 of the substrate 110. After the die 108 has been coupled to the surface 112 of the substrate 110, the flux material 114 is to be removed by exposing the flux material 114 to the fluid 104 ejected by the nozzle 102 into and at the region 106 between the die 108 and the substrate 110. For example, the fluid 104 is a solvent that is selected to remove and deteriorate the flux material 114 such that the flux material 114 is removed from the region 106 between the die 108 and the substrate 110. The region 106 is a gap or space that extends from the surface 112 of the substrate 110 to a surface 118 of the die 108. The fluid 104 is ejected into the region 106 from the nozzle 102 at a pressure that further induces, facilitates, or causes the flux material 114 to move outward from the region 106 removing the flux material 114 from the region 106. After the fluid 104, which is the solvent, the flux material 114 is removed. However, residue of the fluid 104, which is the solvent, remains and, as some of the fluid 104 remains, some of flux may remain, resulting in a solvent and flux residue that remains as well. This solvent and flux residue remaining is removed by, for example, moving the nozzle 102 away from the die 108 and substrate 110 and moving a new nozzle (not shown) in close proximity to the die 108 and the substrate 110. The new nozzle then is activated to eject a new fluid, which is ultra-pure water (UPW), this ejection of the new fluid, which is UPW, removes the solvent and flux residue remaining within the region 106 between the die 108 and the substrate 110. The UPW is ejected at a pressure that further induces, facilitates, or causes the solvent and flux residue to be removed from the region 106. After the new nozzle ejects the UPW into the region 106 to remove the solvent and flux residue, the new nozzle is moved away from the die 108 and the substrate 110 and another new nozzle is moved into close proximity to the die 108 and the substrate 110. The another new nozzle then ejects another new fluid, which is a clean dry air (CDA) to remove and dry the region 106 in which the UPW was previously ejected. In view of this discussion, this process is lengthy by requiring multiple nozzles to eject multiple fluids, as well as having to orient and position multiple nozzles in succession.

When the nozzle 102 is utilized to eject the fluid 104 at and into the region 106 between the die 108 and the substrate 110, the nozzle 102 is moved along the region 106 to remove the flux material 114. This moving of the nozzle 102 requires time and energy to remove the flux material 114 between and within the region 106. Furthermore, as the nozzle 102 is only capable of providing a certain width of fluid, applying a uniform flow to remove the flux material 114 from within the region 106 is difficult increasing the likelihood that at least some solvent and flux residue remains present within the region 106 even after the above process is performed.

When performing the above process to remove the flux material 114 from within the region 106 between the die 108 and the substrate 110, if any solvent and flux residue remains present even after this process is performed, the remaining solvent and flux residue may generate mechanical defects and issues such as cracking or delamination between various layers in the manufacturing of a completed semiconductor device. For example, when the solvent and flux residue remains between the die 108 and the substrate 110 even after performing this cleaning process and an underfill process is performed to fill the region 106 with a packaging material (e.g., molding compound, packaging epoxy, or some other or similar type of suitable packaging material known within the semiconductor industry), the packaging material is cracked after being formed or is partially delaminated to which the packaging material was supposed to be completely and fully adhered and coupled. These mechanical defects may affect an overall performance or efficiency of the manufactured semiconductor device.

Before the above process with respect to removing the flux material 114 is performed, with respect to FIGS. 1A and 1B, a cover 120 is pre-positioned along an edge 122 of the substrate 110. The cover 120 is pre-positioned to hold the substrate 110 stationary in place such that the substrate 110 does not move out of alignment when exposing the region 106 to the fluid 104 ejected by the nozzle 102. For example, while not shown, the substrate 110 will be on a support and the cover 120 applies enough downward force, which is based on the orientation as shown in FIGS. 1A and 1B, to hold the substrate 110 in place on the support. In other words, the cover 120 applies enough force to clamp the substrate 110 between the support and the cover 120 holding the substrate 110 in a stationary position such that the fluid 104 is properly ejected into the region 106 between the die 108 and the substrate 110.

The present disclosure is directed to providing one or more embodiments of a flowhead and a system that includes at least one of the one or more embodiments of the flowhead.

Utilizing the one or more embodiments of the flowhead and the system including at least one of the one or more embodiments of the flowhead of the present disclosure reduces the likelihood of mechanical defects occurring by avoiding or preventing solvent and flux residue from remaining between the die and the substrate as discussed above with respect to FIGS. 1A and 1B. Utilizing the one or more embodiments of the flowhead of the present disclosure speeds up a process in which the flux material is removed from between the die and the substrate as discussed above with respect to FIGS. 1A and 1B. Utilizing the one or more embodiments of the flowheads and the systems removes pre-positioning the cover 120 as discussed above with respect to FIGS. 1A and 1B. At least some of these advantages will become readily apparent in view of the discussion of the one or more embodiments of the flowheads and the systems of the present disclosure.

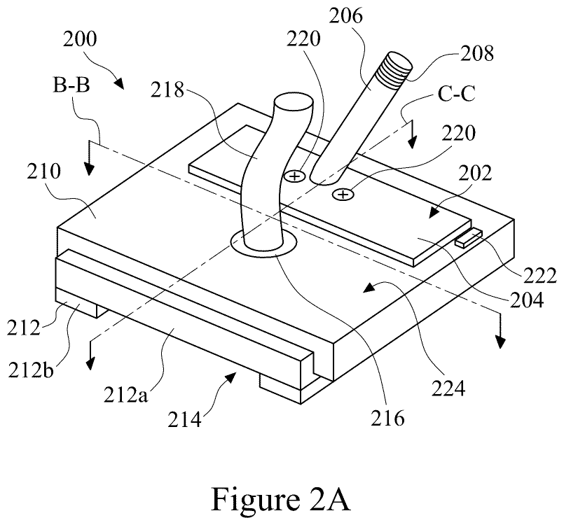

FIG. 2A is a perspective view of flowhead 200, in accordance with some embodiments. The flowhead 200 is configured to, in operation, introduce a respective fluid between a respective die and a respective substrate to remove a flux material from between the die and the substrate.

The flowhead 200 includes a mounting structure 202 having a mounting plate 204 and a mounting protrusion 206. The mounting protrusion 206 protrudes outward from the mounting plate 204 and has a threaded end 208. The mounting plate 204 is fixedly coupled to an end of the mounting protrusion 206 opposite to the threaded end 208 of the mounting protrusion 206. The threaded end 208 of the mounting protrusion 206 is utilized for mounting the flowhead 200 within a processing tool that is capable of being utilized within a semiconductor manufacturing or fabrication plant (i.e., FAB) for manufacturing semiconductor devices. For example, in some situations, the flowhead 200 is mounted to an end of a transfer robot arm (TRA) such that the flowhead 200 can be moved into and out of a processing chamber of the processing tool. For example, in at least one embodiment, the flowhead 200 is mounted to an end effector at the end of the transfer robot arm (TRA). The flowhead 200 may be removable mounted to the transfer robot arm (TRA) such that the flowhead 200 can be replaced once it has reached the end of its useful life span.

The flowhead 200 further includes a gasket plate 210 and a gasket 212 is coupled to or held in place by the gasket plate 210 within a cavity of the gasket plate 210. The gasket 212 includes a first gasket portion 212a and a second gasket portion 212b. The first gasket portion 212a is coupled to the second gasket portion 212b defining the gasket 212. In some embodiments, the first gasket portion 212a and the second gasket portion 212b are made of rubber materials. In some embodiments, the first gasket portion 212a and the second gasket portion 212b are made of different compositions of rubber materials that are fixedly coupled together. In other words, in some embodiments, the first gasket portion 212a and the second gasket portion 212b are made of different materials (e.g., different rubber materials). In some embodiments, the first gasket portion 212a and the second gasket portion 212b are made of the same composition of rubber materials, but are two separate pieces that are fixedly coupled together. In some embodiments, the first gasket portion 212a and the second gasket portion 212b are made of a continuous portion of rubber material such that the first gasket portion 212a and the second gasket portion 212b are not separate portions. The gasket 212 at least partially defines and delimits a fluid flow pathway 214.

A fluid line fitting 216 extends into and through the gasket plate 210 to the gasket 212 (see FIGS. 2A and 2B of the present disclosure). In some embodiments, the fluid line fitting 216 is a quick release fluid fitting that is configured to, in operation, be removed quickly and easily when replacing the flowhead 200 with a new respective flowhead when performing maintenance on a processing tool in which the flowhead 200 is present. This replacement process is generally carried out when it has been determined that the flowhead 200 has reached the end of its useful life span. A fluid line 218 is coupled to and in fluidic communication with the fluid line fitting 216.

In some embodiment, the gasket 212 is held in place within the cavity of the gasket plate 210 by the fluid line fitting 216. In other words, the fluid line fitting 216 being inserted into and receiving the gasket 212 results in the gasket 212 being held in place within the cavity of the gasket plate 212.

One or more fasteners 220 couple the mounting plate 204 to the gasket plate 210. In some embodiments, the one or more fasteners 220 are set screws that are placed into and screwed into place within respective openings in the mounting plate 204 of the mounting structure 202 and the gasket plate 210 fastening the mounting plate 204 of the mounting structure 202 to the gasket plate 210.

A vibration device or unit 222 is present on a surface 224 of the gasket plate 210. The surface 224 is opposite to the gasket 212 and the surface 224 faces away from the gasket 212. In some embodiments, the vibration unit 222 is positioned at a location (e.g., a sidewall or some other suitable surface of the gasket plate 210) somewhere different on the gasket plate 210 as shown in FIG. 2A. The vibration unit 222 is configured to, in operation, be activated to vibrate the flowhead 200 to further induce, facilitate, or cause removal of a flux material between a die and a substrate. For example, by vibrating the flowhead 200 with the vibration unit, the flux material, the die, and the substrate all vibrate agitating the flux material between the die and the substrate further inducing, facilitating, or causing the removal of the flux material between the die and the substrate.

In some embodiments, the vibration unit 222 is an unbalanced motor that is configured to, in operation, vibrate the flowhead 200. In some embodiments, when the vibration unit 222 is the unbalanced motor, the unbalanced motor is configured to, in operation, rotate at rotations per minute (RPM) selected from a range of 1,000 RPMs to 50,000 RPMs, or is selected to be equal to the upper and lower ends of this range.

In some embodiments, the vibration unit 222 is an ultrasonic transducer that is configured to, in operation, vibrate the flowhead 200. In some embodiments, when the vibration unit 222 is the ultrasonic transducer, the ultrasonic transducer is configured to, in operation, vibrate with a frequency selected from a range of 20,000 to 40,000 kilo-Hertz (kHz), or is selected to be equal to the upper and lower ends of this range.

FIG. 2B is a cross-sectional side view of the flowhead 200 taken along line B-B as shown in FIG. 2A, in accordance with some embodiments. FIG. 2C is a cross-sectional side view of the flowhead 200 taken along line C-C as shown in FIG. 2A, in accordance with some embodiments. As shown in FIGS. 2B and 2C, the fluid pathway 214 is in fluid communication with a fluid hole 226. The first gasket portion 212a and the fluid line fitting 216 define and delimit the fluid hole 226. In at least this embodiment of the flowhead 200, the fluid hole 226 is oriented in a direction transverse to the fluid pathway 214 defined and delimited by the first gasket portion 212a and the second gasket portion 212b. The fluid hole 226 extends through the first gasket portion 212a and the fluid line fitting 216. In other words, respective fluid openings extending into and through the first gasket portion 212a and the fluid line fitting 216 define and delimit the fluid hole 226.

As shown in FIGS. 2B and 2C, a second gasket 228 is between a lip portion 230 of the fluid line fitting 216 and the surface 224 of the gasket plate 210. In some embodiments, the second gasket 228 is an O-ring.

FIG. 2D is a bottom side view of the flowhead 200 as shown in FIG. 2A, in accordance with some embodiments. As shown in FIG. 2D, the fluid hole 226 is centrally located along the first gasket portion 212a. As shown in FIG. 2D, the second gasket portion 212b has a C-shape or U-shape. The second gasket portion 212b includes a first sidewall portion 232, a second sidewall portion 234 spaced apart from the first sidewall portion 232, and a third sidewall portion 236 that extends from the first sidewall portion 232 to the second sidewall portion 234 defining the C-shape or the U-shape.

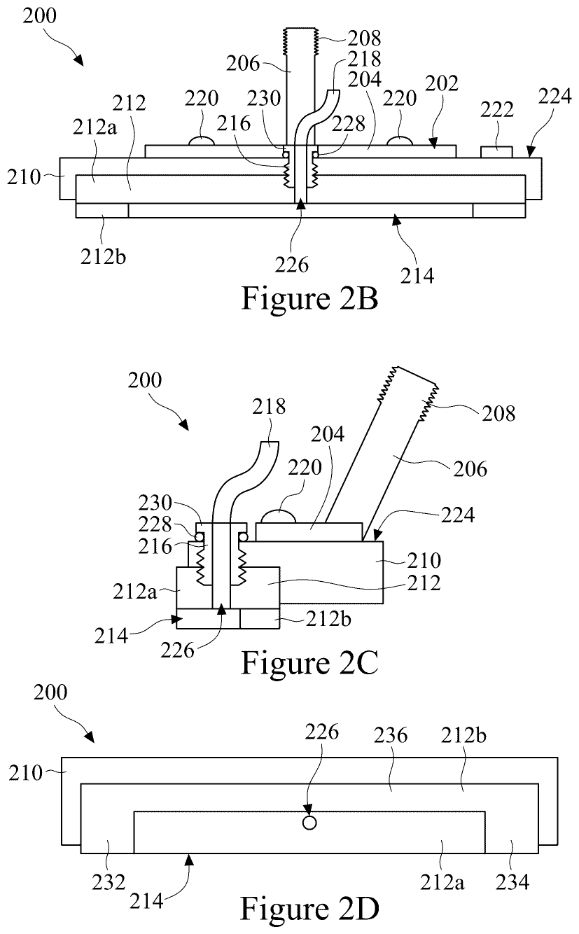

FIG. 3A is a perspective view of a system 300 including a flowhead 302, in accordance with some embodiments. In some embodiments, the flowhead 302 is the same or similar in structure to the flowhead 200 as discussed earlier herein with respect to FIGS. 2A-2D of the present disclosure. Some of the features as shown in FIG. 3 are the same or similar features as described earlier herein with respect to FIGS. 1A, 1B and 2A-2D, and, therefore, are provided with the same or similar reference numerals. For simplicity and brevity of the present disclosure, as these features that are the same or similar have been described in detail with respect to at least one of FIGS. 1A, 1B, and 2A-2D, these features may not be redescribed in detail as follows herein.

As shown in FIG. 3A, the die 108 is coupled to the substrate 110, and the substrate 110 is present on a surface 304 of a support 306. Another vibration unit 308 is on the surface 304 of the support 306, and the another vibration unit 308 is in close proximity to at least one sidewall surface 111 of the plurality of sidewall surfaces 111 of the substrate 110. In some embodiments, the another vibration unit 308 abuts the at least one sidewall surface 111 of the plurality of sidewall surfaces 111 of the substrate 110. The another vibration unit 308 is the same or similar to the vibration unit 222, but the another vibration unit 308 is located on the surface 304 of the support 306 instead of on a respective surface of the flowhead 302.

FIG. 3B is a cross-sectional view of the system 300 taken along the line D-D as shown in FIG. 3A, in accordance with some embodiments. As shown in FIG. 3B, a fluid pathway 310 extends through the flowhead 302. The fluid pathway 310 includes a first portion 310a and a second portion 310b transverse to the first portion 310a. During operation (see FIG. 3B), the flowhead 302 is positioned directly adjacent to or in close proximity to at least one sidewall surface 119 of the plurality of sidewall surfaces 119 of the die 108. While not shown, when the flowhead 302 is the flowhead 200 as shown in FIGS. 2A-2D, the first gasket portion 212a and the second gasket portion 212b of the gasket 212 form a seal with the at least one sidewall 119 of the die 108 and the first surface 112 of the substrate 110, the first portion 310a of the fluid pathway 310 corresponds to the fluid hole 226 (see FIGS. 2B-2D), and the second portion 310b of the fluid pathway 310 corresponds to the fluid flow pathway 214 (see FIGS. 2A-2D). When the flowhead 302 is positioned as shown in FIG. 3B, the flowhead 302 forms seals with the first surface 112 of the substrate 110 and the at least one sidewall surface 119 of the die 108. When the flowhead 302 is positioned on the first surface 112 of the substrate 110, the flowhead 302 acts to hold the substrate 110 in place on the surface 304 of the support 306.

An arrow 312 as shown in FIGS. 3A and 3B is representative of a flow direction of a fluid into and through the fluid line 218. The fluid (e.g., a clean dry air (CDA), ultra-pure water (UPW), a solvent, or some other similar or like type of fluid) enters the fluid line 218 and passes through the fluid line 218 into the first portion 310a of the fluid pathway 310, then successively flows into the second portion 310b of the fluid pathway 310, and then exits the second portion 310b of the fluid pathway 310 and is ejected into the region 106 between the surface 118 of the die and the surface 112 of the substrate. This fluid is ejected into the region 106 to remove the flux material 114 present within the region 106 between the surface 118 of the die 108 and the surface 112 of the substrate 110.

FIG. 3C is a cross-sectional top down view of the system 300 for removing the flux material 114 from within the region 106 between the surface 118 of the die 108 and the surface 112 of the substrate 110 taken along line E-E as shown in FIG. 3B, in accordance with some embodiments. In this embodiment of the system 300 as shown in FIG. 3C, the second portion 310b of the fluid pathway 310 of the flowhead 302 includes a plurality of fluid channels 314 and a main channel 316 that is in fluid communication with the plurality of channels 314. The main channel 316 is in fluid communication with the first portion 310a of the fluid pathway 310, and, in some embodiments, the main channel 316 may be considered as being part of the first portion 310a of the fluid pathway 310.

A plurality of arrows 318 as shown in FIG. 3C are representative of a flow of a fluid through the plurality of channels 314. Another plurality of arrows 319 as shown in FIG. 3C are representative of the flow of the fluid within the region 106 between the surface 118 of the die 108 and the surface 112 of the substrate 110. The plurality of arrows 319 illustrate that the flux material 114 is removed from between the plurality of solder balls 116 and is removed from within the region 106 by the ejection of the fluid from the plurality of channels 314 into the region 106.

Each adjacent channel of the plurality of channels 314 is offset from other adjacent channels of the plurality of channels 314 by an angle 320. The angle 320 is selected from a range ranging from 0 to 90 degrees.

The flowhead 302 includes a plurality of sidewalls 322. An upper sidewall 322 of the flowhead 302 based on the orientation as shown in FIG. 3C is spaced inward from the upper sidewall 111 of the substrate 110, the lower sidewall 322 of the flowhead 302 based on the orientation as shown in FIG. 3C is spaced inward from the lower sidewall 111 of the substrate 110, and the rightmost sidewall 322 of the flowhead 302 based on the orientation as shown in FIG. 3C is spaced inward from the rightmost sidewall 111 of the substrate 110.

A first dimension X as shown in FIG. 3C extends from a first outermost edge 324 of the uppermost channel 314 to the uppermost sidewall 111 of the substrate 110. In at least one embodiment, the first dimension X is selected from a range ranging from 0 millimeters (mm) to 30 millimeters (mm), or is equal to the upper and lower ends of this range.

A second dimension Y as shown in FIG. 3C extends from a second outermost edge 326 of the lowermost channel 314 to the lowermost sidewall 111 of the substrate 110. In at least one embodiment, the second dimension Y is selected from a range ranging from 0 millimeters (mm) to 30 millimeters (mm), or is equal to the upper and lower ends of this range.

As shown in FIG. 3C, the upper outermost edge 324 and the lower outermost edge 326 are spaced outward form the upper outermost sidewall 119 of the die 108 and the lower outermost sidewall 119 of the die 108, respectively.

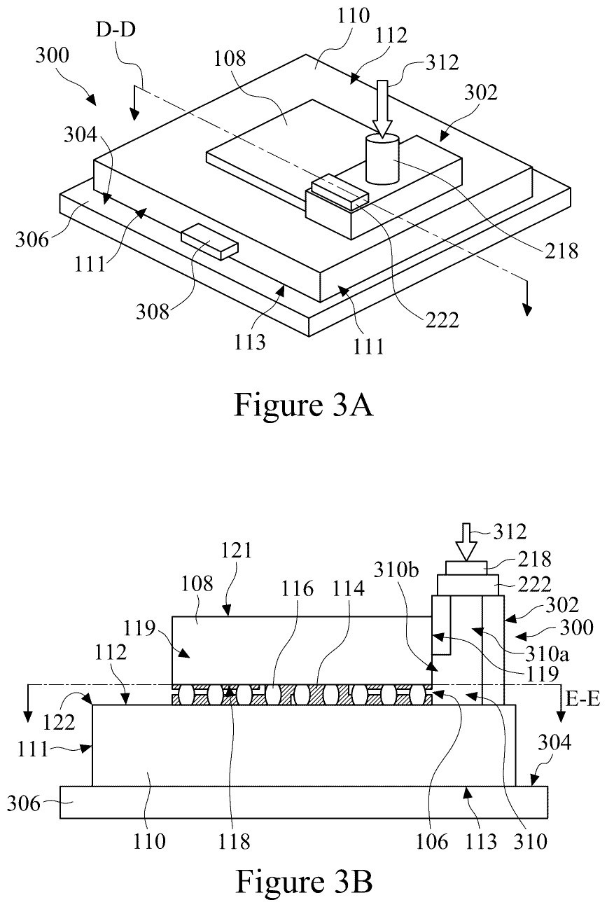

FIG. 4 is a cross-sectional top down view of the system 300 for removing the flux material 114 between the die 108 and the substrate 110 taken along line E-E as shown in FIG. 3B, in accordance with some embodiments. As the embodiment of the system 300 as shown in FIG. 4 includes several of the same or similar features of the embodiment of the system 300 as shown in FIG. 3C, for the sake of simplicity and brevity of the present disclosure, the details of these same or similar features as already described with respect to FIG. 3C may not be reproduced herein with respect to FIG. 4.

In this embodiment of the system 300 as shown in FIG. 4, the second portion 310b of the fluid pathway 310 of the flowhead 302 is a channel 328. In other words, unlike the embodiment of the flowhead 302 as shown in FIG. 3C that includes the plurality of channels 314, the flowhead 302 in the embodiment as shown in FIG. 4 only has a single, continuous channel 328 that is in fluid communication with the first portion 310a of the fluid pathway 310.

In this embodiment of the system 300 as shown in FIG. 4, the first dimension X as shown in FIG. 4 extends from a first outermost edge 324 of the channel 328 to the uppermost sidewall 111 of the substrate 110. In at least one embodiment, the first dimension X is selected from a range ranging from 0 millimeters (mm) to 30 millimeters (mm), or is equal to the upper and lower ends of this range.

In this embodiment of the system 300 as shown in FIG. 4, the second dimension Y as shown in FIG. 4 extends from a second outermost edge 326 of the channel 328 to the lowermost sidewall 111 of the substrate 110. In at least one embodiment, the second dimension Y is selected from a range ranging from 0 millimeters (mm) to 30 millimeters, or is equal to the upper and lower ends of this range.

As shown in FIG. 4, the upper outermost edge 324 and the lower outermost edge 326 are spaced outward form the upper outermost sidewall 119 of the die 108 and the lower outermost sidewall 119 of the die 108, respectively. In other words, the upper outermost edge 324 is spaced outward from the upper outermost sidewall 119 of the die 108, and the lower outermost edge 326 is spaced outward from the lower outermost sidewall 119 of the die 108.

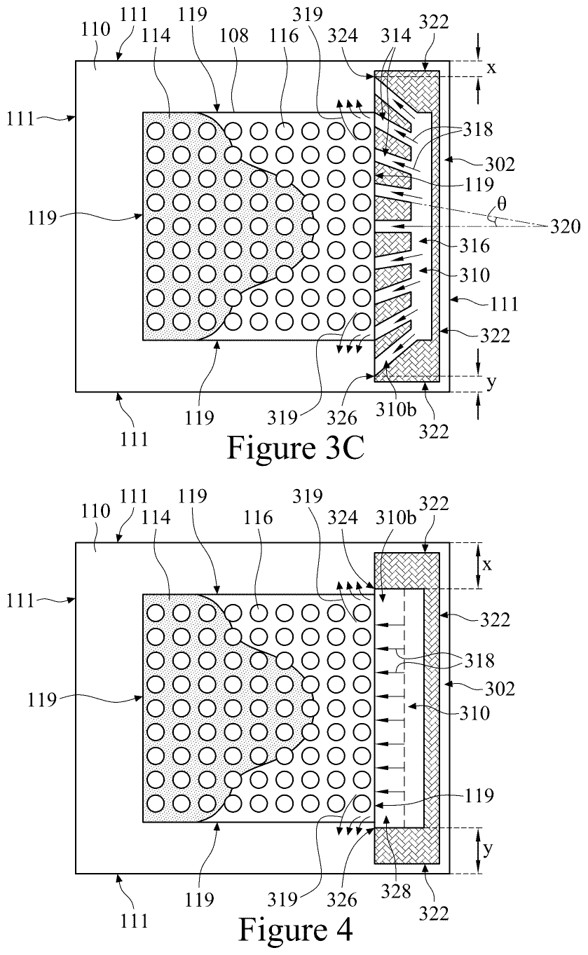

FIG. 5 is a cross-sectional top down view of the system 300 for removing the flux material 114 between the die 108 and the substrate 110 taken along line E-E as shown in FIG. 3B, in accordance with some embodiments. As the embodiment of the system 300 as shown in FIG. 5 includes several of the same or similar features of the embodiment of the system 300 as shown in FIG. 3C, for the sake of simplicity and brevity of the present disclosure, the details of these same or similar features as already described with respect to FIG. 3C may not be reproduced herein with respect to FIG. 5.

In this embodiment of the system 300 as shown in FIG. 5, a third dimension E as shown in FIG. 5 extends from a first outermost edge 324 of the channel 328 to the upper outermost sidewall 119 of the die 108. In at least one embodiment, the third dimension E is selected from a range ranging from 0 millimeters (mm) to 20 millimeters (mm), or is equal to the upper and lower ends of this range.

In this embodiment of the system 300 as shown in FIG. 5, a fourth dimension F as shown in FIG. 5 extends from a second outermost edge 326 of the channel 328 to the lower outermost sidewall 119 of the die 108. In at least one embodiment, the fourth dimension F is selected from a range ranging from 0 millimeters (mm) to 20 millimeters (mm), or is equal to the upper and lower ends of this range.

As shown in FIG. 5, the upper outermost edge 324 and the lower outermost edge 326 are spaced inward form the upper outermost sidewall 119 of the die 108 and the lower outermost sidewall 119 of the die 108, respectively. In other words, the upper outermost edge 324 is spaced inward from the upper outermost sidewall 119 of the die 108, and the lower outermost edge 326 is spaced inward from the lower outermost sidewall 119 of the die 108.

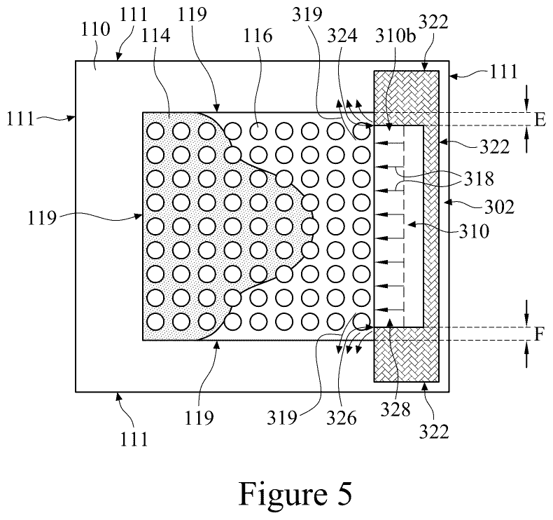

FIG. 6 is a cross-sectional top down view of the system 300 for removing the flux material 114 between the die 108 and the substrate 110 taken along line E-E as shown in FIG. 3B, in accordance with some embodiments. As the embodiment of the system 300 as shown in FIG. 6 includes several of the same or similar features of the embodiment of the system 300 as shown in FIG. 3C, for the sake of simplicity and brevity of the present disclosure, the details of these same or similar features as already described with respect to FIG. 3C may not be reproduced herein with respect to FIG. 6.

In this embodiment of the system 300 as shown in FIG. 6, the third dimension E as shown in FIG. 6 extends from a first outermost edge 324 of the uppermost channel 314 to the upper outermost sidewall 119 of the die 108. In at least one embodiment, the third dimension E is selected from a range ranging from 0 millimeters to 20 millimeters (mm), or is equal to the upper and lower ends of this range.

In this embodiment of the system 300 as shown in FIG. 6, the fourth dimension F as shown in FIG. 6 extends from a second outermost edge 326 of the lowermost channel 314 to the lower outermost sidewall 119 of the die 108. In at least one embodiment, the fourth dimension F is selected from a range ranging from 0 millimeters to 20 millimeters (mm), or is equal to the upper and lower ends of this range.

As shown in FIG. 6, the first outermost edge 324 and the second outermost edge 326 are spaced inward form the upper outermost sidewall 119 of the die 108 and the lower outermost sidewall 119 of the die 108, respectively. In other words, the first outermost edge 324 is spaced inward from the upper outermost sidewall 119 of the die 108, and the second outermost edge 326 is spaced inward from the lower outermost sidewall 119 of the die 108.

The embodiment of the flowhead 302 as shown in FIG. 6 is essentially the same as the embodiment of the flowhead 302 as shown in FIG. 3C. However, unlike the embodiment of the flowhead 302 as shown in FIG. 3C in which the first outermost edge 324 and the second outermost edge 326 are spaced outward from the uppermost sidewall 119 of the die 108 and the lowermost sidewall 119 of the die 108, respectively, the first outermost edge 324 and the second outermost edge 326 are spaced inward from the uppermost sidewall 119 of the die 108 and the lowermost sidewall 119 of the die 108, respectively. In other words, the first outermost edge 324 is spaced inward from the uppermost sidewall 119 of the die 108 and the second outermost edge 326 is spaced inward from the lowermost sidewall 119 of the die 108. In other words, the plurality of channels 314 of the second portion 310b of the fluid pathway 310 do not extend outward from the uppermost sidewall 119 of the die 108 and the lowermost sidewall 119 of the die 108.

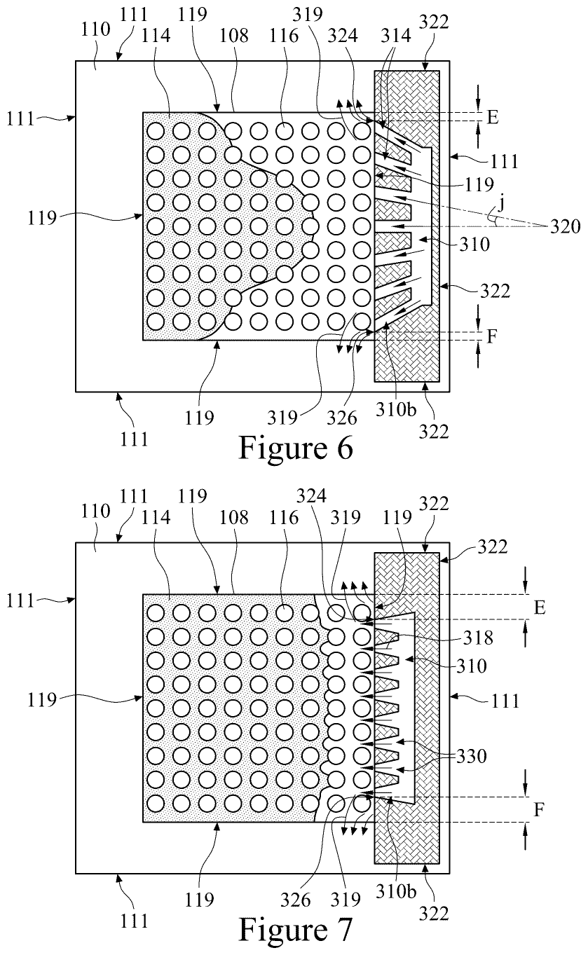

FIG. 7 is a cross-sectional top down view of the system 300 for removing the flux material 114 between the die 108 and the substrate 110 taken along line E-E as shown in FIG. 3B, in accordance with some embodiments. As the embodiment of the system 300 as shown in FIG. 7 includes several of the same or similar features of the embodiment of the system 300 as shown in FIG. 3C, for the sake of simplicity and brevity of the present disclosure, the details of these same or similar features as already described with respect to FIG. 3C may not be reproduced herein with respect to FIG. 7.

In this embodiment of the system 300 as shown in FIG. 7, the embodiment of the flowhead 302 includes a plurality of channels 330. In this embodiment of the flowhead 302, the plurality of channels 330 are tapered such that the plurality of channels 330 become narrower as one moves towards the die 108. In this embodiment of the flowhead 302, the plurality of channels 330 may be referred to as a plurality of nozzles or some other similar or like reference.

In this embodiment of the system 300 as shown in FIG. 7, the third dimension E as shown in FIG. 7 extends from a first outermost edge 324 of an uppermost channel 330 to the upper outermost sidewall 119 of the die 108. In at least one embodiment, the third dimension E is selected from a range ranging from 0 millimeters (mm) to 20 millimeters (mm), or is equal to the upper and lower ends of this range.

In this embodiment of the system 300 as shown in FIG. 7, the fourth dimension F as shown in FIG. 3C extends from a second outermost edge 326 of the lowermost channel 330 to the lower outermost sidewall 119 of the die 108. In at least one embodiment, the fourth dimension F is selected from a range ranging from 0 millimeters (mm) to 20 millimeters (mm), or is equal to the upper and lower ends of this range.

As shown in FIG. 7, the first outermost edge 324 and the second outermost edge 326 are spaced inward form the uppermost sidewall 119 of the die 108 and the lowermost sidewall 119 of the die 108, respectively. In other words, the first outermost edge 324 is spaced inward from the upper outermost sidewall 119 of the die 108, and the second outermost edge 326 is spaced inward from the lower outermost sidewall 119 of the die 108.

While not shown, in an alternative embodiment of the flowhead 302 as shown in FIG. 7, the first outermost edge 324 and the second outermost edge 326 are spaced outward from the uppermost sidewall 119 of the die 108 and the lowermost sidewall 119 of the die 108, respectively. In other words, in this alternative embodiment of the flowhead 302 as shown in FIG. 7, the first outermost edge 324 is spaced outward from the uppermost sidewall 119 of the die 108, and the second outermost edge 326 is spaced outward from the lowermost sidewall 119 of the die 108. In this alternative embodiment of the flowhead 302, the plurality of channels 330 extend outward from the uppermost sidewall 119 of the die 108 and extend outward from the lowermost sidewall 119 of the die 108.

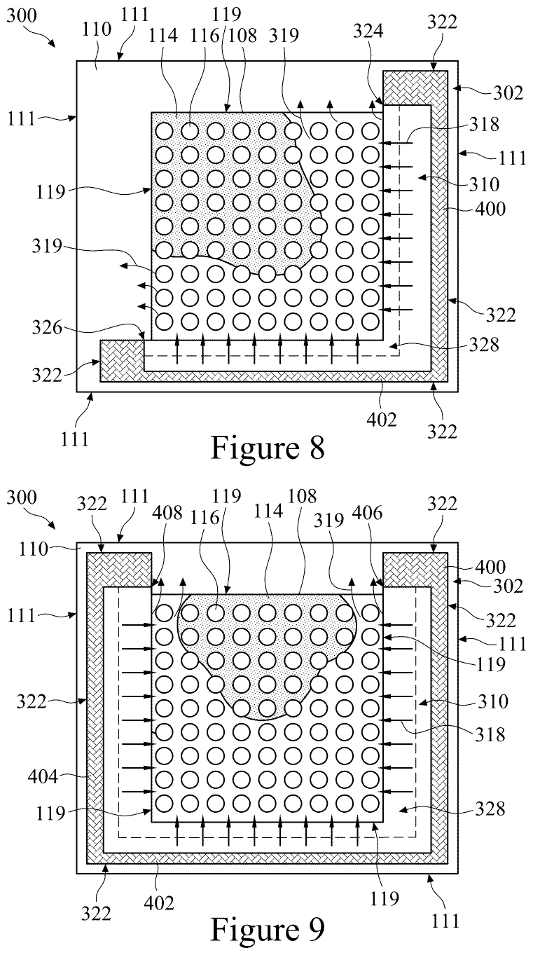

FIG. 8 is a cross-sectional top down view of the system 300 for removing the flux material 114 between the die 108 and the substrate 110 taken along line similar to E-E as shown in FIG. 3B, in accordance with some embodiments. As the embodiment of the system as shown in FIG. 8 has several of the same or similar features of the embodiment of the system as shown in FIG. 3C, for the sake of simplicity and brevity of the present disclosure, the details of these same or similar features as already described with respect to FIG. 3C may not be reproduced fully herein with respect to FIG. 8.

In this embodiment of the system 300 as shown in FIG. 8, the embodiment of the flowhead 302 includes a reverse L-shape based on the orientation of the flowhead 302 as shown in FIG. 8. The flowhead 302 as shown in FIG. 8 includes a first portion 400 and a second portion 402 that is transverse to the first portion 400. In this embodiment of the flowhead 302 as shown in FIG. 8, the second portion 402 is perpendicular to the first portion 400. In some alternative embodiments of the reverse L-shape flowhead 302 as shown in FIG. 8, the second portion 402 is at some other angle other than 90 degrees (i.e., perpendicular or orthogonal) relative to the first portion 400.

As the flowhead 302 has the reverse L-shape based on the orientation of the flowhead 302 as shown in FIG. 8, the channel 328 has the reverse L-shape as well. In other words, unlike the embodiment of the flowhead 302 as shown in FIG. 3C that includes the plurality of channels 314, the flowhead 302 in the embodiment as shown in FIG. 8 only has a single, continuous channel 328 that is in fluid communication with the first portion 310a of the fluid pathway 310. In other words, the channel 328 is essentially the second portion 310b of the fluid pathway 310 and has the reverse L-shape, and the first portion 310a of the fluid pathway 310 also has the reverse L-shape as shown in FIG. 8. As the flowhead 302 has the reverse L-shape based on the orientation of the flowhead 302 as shown in FIG. 8, the flowhead 302 abuts or is in close proximity to at least two of the outermost sidewalls 119 of the die 108 (i.e., the rightmost outermost sidewall 119 of the die 108 and the lowermost outermost sidewall 119 of the die 108).

The upper outermost edge 324 is spaced outward from the upper outermost sidewall 119 of the die 108, and the lower outermost edge 326 is spaced outward from the left outermost sidewall 119 of the die 108. While not shown, in an alternative embodiment of the flowhead 302 as shown in FIG. 8, the upper outermost edge 324 is spaced inward from the upper outermost sidewall 119 of the die 108, and the lower outermost edge 326 is spaced inward from the left outermost sidewall 119 of the die 108.

In an alternative embodiment of the flowhead 302 with the reverse L-shape as shown in FIG. 8, the single, continuous channel 328 is replaced by a plurality of channels that are separate and distinct from each other. The plurality of channels that are separate and distinct from each other are the same or similar to the plurality of channels 314, 330 as shown in other embodiments of the flowhead 302 of the present disclosure.

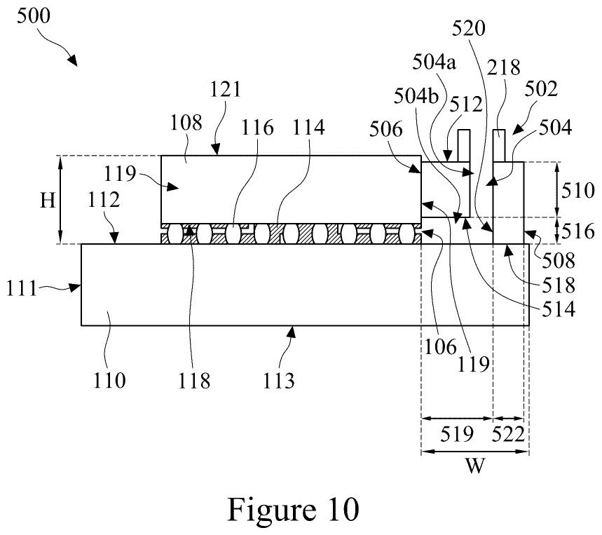

FIG. 9 is a cross-sectional top down view of the system 300 for removing the flux material 114 between the die 108 and the substrate 110 taken along line similar to E-E as shown in FIG. 3B, in accordance with some embodiments. As the embodiment of the system as shown in FIG. 9 has several of the same or similar features of the embodiment of the system as shown in FIG. 3C, for the sake of simplicity and brevity of the present disclosure, the details of these same or similar features as already described with respect to FIG. 3C may not be reproduced fully herein with respect to FIG. 9.

In this embodiment of the system 300 as shown in FIG. 9, the embodiment of the flowhead 302 includes a U-shape based on the orientation of the flowhead 302 as shown in FIG. 9. The flowhead 302 as shown in FIG. 9 includes a first portion 400, a second portion 402 that is transverse to the first portion 400, and a third portion 404 transverse to the second portion 402. In this embodiment of the flowhead 302 as shown in FIG. 9, the second portion 402 is perpendicular to the first portion 400, and the third portion 404 is perpendicular to the second portion 402 such that the third portion 404 is parallel to the first portion 400. In some alternative embodiments of the U-shape flowhead 302 as shown in FIG. 9, the second portion 402 is at some other angle other than 90 degrees (i.e., perpendicular or orthogonal) relative to the first portion 400, and the third portion 404 is at some other angle other than 90 degrees (i.e., perpendicular or orthogonal) relative to the second portion 402. In some alternative embodiments of the U-shape flowhead 302 as shown in FIG. 9, the third portion 404 is not parallel with the first portion 400.

As the flowhead 302 has the U-shape based on the orientation of the flowhead 302 as shown in FIG. 9, the channel 328 has the U-shape as well. In other words, unlike the embodiment of the flowhead 302 as shown in FIG. 3C that includes the plurality of channels 314, the flowhead 302 in the embodiment as shown in FIG. 9 only has a single, continuous channel 328 that is in fluid communication with the first portion 310a of the fluid pathway 310. In other words, the channel 328 is essentially the second portion 310b of the fluid pathway 310 and has the U-shape, and the first portion 310a of the fluid pathway 310 also has the U-shape as shown in FIG. 9. As the flowhead 302 has the U-shape based on the orientation of the flowhead 302 as shown in FIG. 9, the flowhead 302 abuts or is in close proximity to at least three of the outermost sidewalls 119 of the die 108 (i.e., the leftmost outermost sidewall 119 of the die 108, the lowermost outermost sidewall 119 of the die 108, and the rightmost outermost sidewall 119 of the die 108).

A first upper outermost edge 406 is spaced outward from the upper outermost sidewall 119 of the die 108, and a second upper outermost edge 408 is spaced outward from the upper outermost sidewall 119 of the die 108. While not shown, in an alternative embodiment of the flowhead 302 as shown in FIG. 9, the first upper outermost edge 406 is spaced inward from the upper outermost sidewall 119 of the die 108, and the second upper outermost edge 408 is spaced inward from the upper outermost sidewall 119 of the die 108.

In an alternative embodiment of the flowhead 302 with the U-shape as shown in FIG. 9, the single, continuous channel 328 is replaced by a plurality of channels that are separate and distinct from each other. The plurality of channels that are separate and distinct from each other are the same or similar to the plurality of channels 314, 330 as shown in other embodiments of the flowhead 302 of the present disclosure.

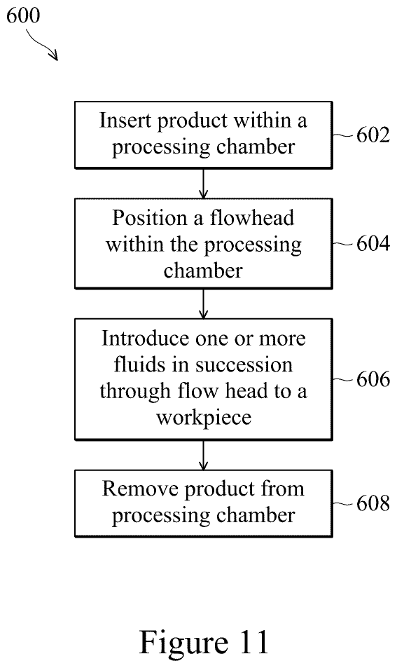

FIG. 10 is a cross-sectional side view of a system 500 for removing the flux material 114 from between the die 108 and the substrate 110, in accordance with some embodiments. The cross-section is taken along a line the same or similar to line D-D as shown in FIG. 3A of the present disclosure. Some of the features as shown in FIG. 10 are the same or similar features as described earlier herein with respect to FIGS. 1A, 1B, 2A-2D, and 3A-3C, and, therefore, are provided with the same or similar reference numerals. For simplicity and brevity of the present disclosure, as these features that are the same or similar have been described in detail with respect to at least one of FIGS. 1A, 1B, 2A-2D, and 3A-3C these features may not be redescribed in detail as follows herein.

The system 500 includes a flowhead 502 having a fluid pathway 504. A first portion 504a of the fluid pathway 504 is transverse to a second portion 504b of the fluid pathway. The first portion 504 a is in fluid communication with the fluid line 218, and the second portion 504 b is in fluid communication with the first portion 504a.

A height H extends from the another surface 121 of the die 108 to the surface 112 of the substrate 110. A width W of the flowhead 502 extends from an inner sidewall 506 of the flowhead 502 to a sidewall 111 (i.e., the right sidewall 111 of the substrate 110 based on the orientation of the system 500 as shown in FIG. 10) of the substrate 110.

An outer sidewall 508 of the flowhead 502 is opposite to the inner sidewall 506 of the flowhead 502. As shown in FIG. 10, the inner sidewall 506 the flowhead 502 abuts a respective outermost sidewall 119 of the die 108 (i.e., the right outermost sidewall 119 of the die 108 based on the orientation of the system 500 as shown in FIG. 10).

A fifth dimension 510 of the flowhead 502 extends from an upper surface 512 of the flowhead 502 to a first internal surface 514 of the flowhead 502. The first internal surface 514 of the flowhead 502 defines and delimits the fluid pathway 504 of the flowhead 502. The upper surface 512 of the flowhead 502 is transverse to the inner sidewall 506 and the outer sidewall 508, and the upper surface 512 is opposite to the first internal surface 514 and faces away from the first internal surface 514.

A sixth dimension 516 of the flowhead 502 extends from the first internal surface 514 to a lower surface 518 of the flowhead 502. The lower surface 518 of the flowhead 502 abuts and contacts the surface 112 of the substrate 110. The lower surface 518 of the flowhead 502 is opposite to the upper surface 512 of the flowhead 502, and the lower surface 518 of the flowhead 502 faces away from the upper surface of the flowhead 502.

In this embodiment of the flowhead 502, a summation of the fifth dimension 510 and the sixth dimension 516 is less than the height H. In some alternative embodiments of the flowhead 502, the summation of the fifth dimension 510 and the sixth dimension 516 is greater than the height H or is equal to the height H.

In this embodiment of the flowhead 502, the fifth dimension 510 is less than the height H and the sixth dimension 516 is less than the height H. In this embodiment of the flowhead 502, the fifth dimension 510 is less than the sixth dimension 516. In some alternative embodiments of the flowhead 502, the fifth dimension 510 and the sixth dimension 516 are adjusted to selected values depending on the situation in which the flowhead 502 is to be utilized in removing the flux material 114 from within the region 106 between the die 108 and the substrate 110. For example, the fifth dimension 510 and the sixth dimension 516 are adjusted to increase or decrease a pressure of fluid ejected from the fluid pathway 504 into the region 106 to efficiently and effectively remove the flux material 114 without damaging the solder balls 116 within the region 106.

A seventh dimension 519 extends from inner sidewall 506 of the flowhead 502 to a second internal surface 520 of the flowhead 502. The second internal surface 520 defines and delimits the fluid pathway 504 of the flowhead 502. The second internal surface 520 is transverse to the first internal surface 514. The second internal surface 520 is opposite to the outer sidewall 508 of the flowhead 502. In this embodiment of the flowhead 502, the seventh dimension 519 is less than the width W.

An eighth dimension 522 extends from the second internal surface 520 of the flowhead 502 to the outer sidewall 508 of the flowhead 502. In this embodiment of the flowhead 502, the eighth dimension 522 is less than the width W.

In this embodiment of the system 500, the summation of the seventh dimension 519 and the eighth dimension 522 is less than the width W. In other words, the outer sidewall 508 is spaced inward from the sidewall 111 (i.e., the right sidewall 111 of the substrate 110 based on the orientation of the system 500 as shown in FIG. 10) of the substrate 110. In alternative embodiments of the system 500, the outer sidewall 508 can be flush or coplanar with the right sidewall 111 of the substrate 110 when the flowhead 502 is placed on the surface 112 of the substrate 110 such that the summation of the seventh dimension 519 and the eight dimension 522 is equal to the width W. In some alternative embodiments of the flowhead 502, the seventh dimension 519 and the eight dimension 522 are adjusted to selected values depending on the situation in which the flowhead 502 is to be utilized in removing the flux material 114 from within the region 106 between the die 108 and the substrate 110. For example, the seventh dimension 519 and the eight dimension 522 are adjusted to increase or decrease a pressure of fluid ejected from the fluid pathway 504 into the region 106 to efficiently and effectively remove the flux material 114 without damaging the solder balls 116 within the region 106.

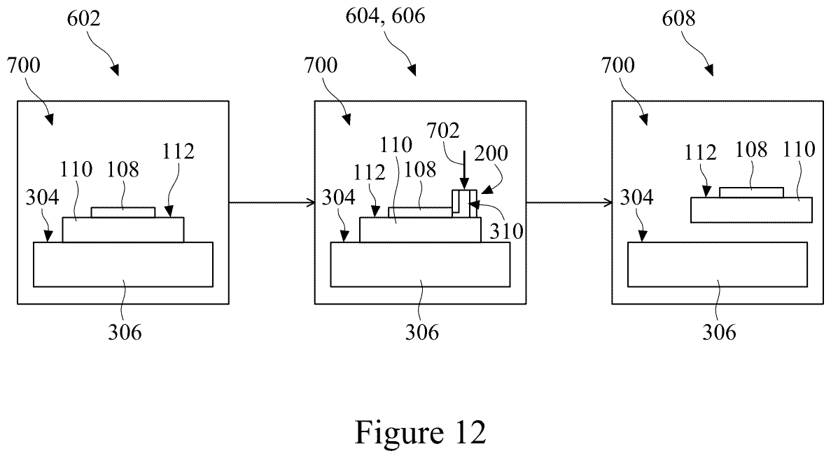

FIG. 11 is a flowchart 600 of a method of removing the flux material 114 from the region 106 between the die 108 and the substrate 110, in accordance with some embodiments. The flowchart 600 includes a first step 602, a second step 604, a third step 606, and a fourth step 608.

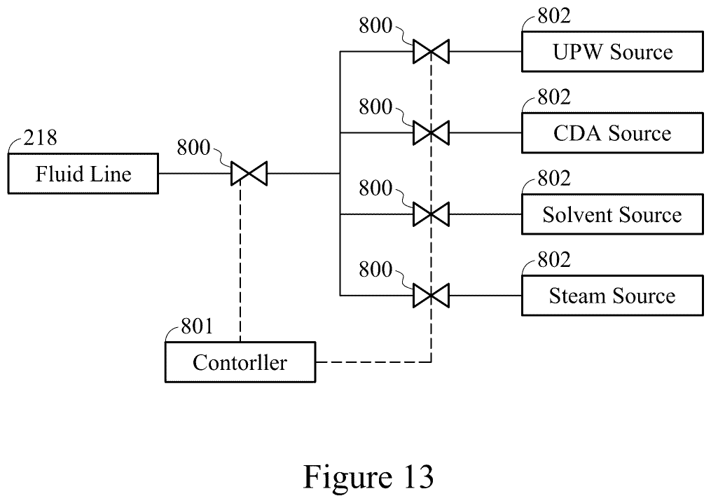

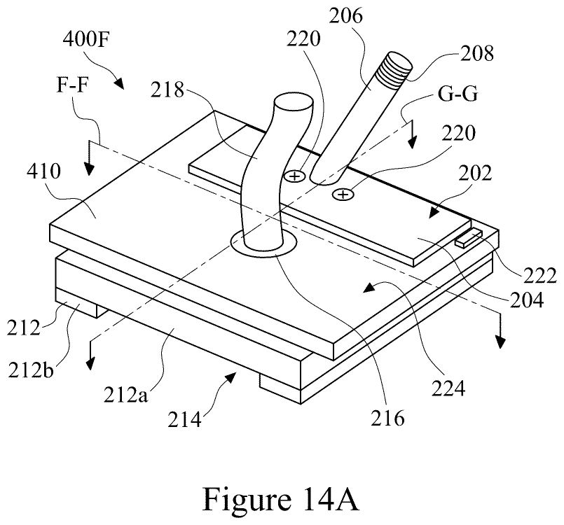

FIG. 12 is a flow diagram of respective steps of the flowchart 600 of the method of removing the flux material 114 from the region 106 between the die 108 and the substrate as shown in FIG. 11, in accordance with some embodiments. The details of respective steps in the flowchart 600 as shown in FIG. 11 will be discussed in conjunction with the flowchart of these respective steps as shown in FIG. 12. FIG. 13 is directed to a schematic diagram of one or more fluid sources in fluid communication with the flowhead 200 through the fluid line 218.

In the first step 602, a workpiece, which includes the die 108 already being coupled to the substrate 110 by the flux material 114 and the solder balls 116 within the region 106 between the die 108 and the substrate 110, is positioned on the surface 304 of the support 306. For example, the workpiece is positioned on the surface 304 of the support 306 by a transfer robot arm (TRA) or some other suitable technique to place the workpiece on the surface 304 of the support 306. Once the workpiece is placed on the surface 304 of the support 306, the second surface 113 of the substrate 110 rests on the surface 304 of the support 306. In some embodiments, the support 306 is present within a processing chamber 700 of a workpiece processing tool (not shown). The workpiece processing tool can be any suitable workpiece processing tool to process the workpiece including the die 108 and the substrate 110.

After the first step 602 in which the workpiece is positioned on and rests on the surface 304 of the support 306, in the second step 604 the flowhead 200 (see FIGS. 2A-2D of the present disclosure) is inserted into the processing chamber 700 and is placed on the surface 112 of the substrate 110. When the flowhead 200 is placed on the surface 112 of the substrate 110, the gasket 212 contacts and abuts the surface 112 of the substrate 110. For example, a lower surface of the second gasket portion 212b contacts and abuts the surface 112 of the substrate 110. The lower surface of the second gasket portion 212b contacting and abutting the surface 112 of the substrate 110 forms a seal between the surface 112 of the substrate 110 and the lower surface of the second gasket portion 212b. When the flowhead 200 is placed on the surface 112 of the substrate 110, one or more respective sidewalls of the first gasket portion 212a and one or more respective sidewalls of the second gasket portion 212b abuts and contacts at least one sidewall of the sidewalls 111 of the die 108 forming a seal between the one or more respective sidewalls of the first gasket portion 212a and the second gasket portion 212b and the at least one sidewall of the sidewalls 111 of the die 108.

When the flowhead 200 is placed on the surface 112 of the substrate 110, the flowhead 200 is pressed downward with enough downward force onto the surface 112 of the substrate 110 to hold the substrate 110 in place. This downward force is selected to keep and hold the substrate 110 in place, which keeps and holds the workpiece (i.e., the die 108 and the substrate 110) in place along the surface 304 of the support 306. In other words, the substrate 110 is clamped between the flowhead 200 and the support 306 due to enough downward force being applied to the substrate 110 by the flowhead 200. Applying enough downward force on substrate 110 with the flowhead 200 keeps the workpiece (i.e., the die and the substrate 110) in place when removing the flux material 114 causing the flux material 114 to be more readily and quickly removed from the region 106 between the die 108 and the substrate 110.

After the second step 604 in which the flowhead 200 is positioned on the surface 112 of the substrate 110, in a third step 606 one or more fluids are passed into and through the fluid pathway 214 and the fluid hole 226 of the flowhead 200. For example, the one or more fluids includes at least one of or some of a steam, a solvent, an ultra-pure water (UPW), a clean dry air (CDA), or some other similar or like type of fluid that is suitable for being ejected from the flowhead 200 into the region 106 between the die 108 and the substrate 110 to assist in removing the flux material 114 present within the region 106. The one or more fluids being introduced into the fluid hole 226 and successively into the fluid pathway 214 is represented by an arrow 702 as shown in FIG. 12. For example, in at least one embodiment of the third step 606, the steam (which may be steam generating using UPW) is ejected from the fluid pathway 214 into the region 106 between the die 108 and the substrate 110 with enough pressure to facilitate the deterioration and removal of the flux material 114 without having to eject a solvent through the flowhead 200 beforehand. After the steam is ejected from the fluid pathway 214 into the region and the flux material 114 is mostly or entirely removed from the region 106 between the die 108 and the substrate 110, the CDA is then in succession ejected through the fluid pathway 214 into the region to further facilitate removing any loose material of the flux material 114 remaining after ejecting the steam, as well as drying the region 106 between the die 108 and the substrate 110 to increase the speed at which the workpiece is processed. The steam generally increases the speed at which the removal of the flux material 114 can occur as the steam generally results in a smaller amount of residue remaining within the region 106, and, therefore, when the CDA is introduced in succession after the steam, the CDA more quickly and easily dries any remaining liquid that remains within the region 106 after introducing the steam. In other words, utilizing the steam followed by the CDA more readily and quickly dries the region 106 between the die 108 and the substrate 110.

In at least one alternative embodiment of the third step 606, a solvent is ejected into the region 106 through the fluid pathway 214 of the flowhead 200 to deteriorate and remove the flux material 114 from the region 106 between the die 108 and the substrate 110. After the solvent is introduced, the UPW is ejected from the fluid pathway 214 of the flowhead 200 into the region 106 removing any solvent and flux residue and further facilitating removal of any remaining loose portions of the flux material 114. After the UPW is ejected from the fluid pathway 214, the CDA is ejected from the fluid pathway 214 of the flowhead 200 to dry the region 106 between the die 108 and the substrate 110 while further facilitating removal of any loose portions of the flux material 114 still remaining within the region 106 between the die 108 and the substrate 110.

In some embodiments of the flowchart 600, during the ejection of these one or more fluids into the region 106 between the die 108 and the substrate 110, the vibration unit 222 and the another vibration unit 308 are activated to vibrate the flowhead 200 and the support 306 to further facilitate the removal of the flux material 114 from within the region 106. For example, in some embodiments, the vibration ranges from 20,000 to 40,000 kilo-Hertz (kHz), or is equal to the upper and lower ends of this range. In some embodiments, the vibration unit 222 includes a motor that rotates from 1,000 to 50,000 rotations per minute (rpm), or is equal to the upper and lower ends of this range.

The various fluids as set forth above are ejected in succession without having to move the flowhead 200 from the position on the surface 112 of the substrate 110 as shown in FIG. 12. For example, the solvent, the UPW, and the CDA can all be ejected in any order as desired by being introduced through the fluid line 218. For example, as shown in FIG. 13, the steam, CDA, UPW, solvent, or any other suitable type of fluid in a liquid, gaseous, or semi-gaseous state is in fluid communication with the fluid line 218 through a plurality of valves 800. In at least one embodiment, a controller 801 is in electrical communication with each respective valve of the plurality of valves 800. The controller 801 is configured to, in operation, send respective control signals to the plurality of valves 800 to open and close the plurality of valves 800 to introduce a selected one of the various respective fluids (e.g., steam, UPW, CDA, solvent, or some other suitable or like type of fluid that may be ejected from the flowhead 200 into the region 106 between the die 108 and the substrate 110 to remove the flux material 114 from the region 106). As shown in FIG. 13, there is a plurality of sources 802 in fluid communication with respective ones of the plurality of valves 800. For example, there is a UPW source, a CDA source, a solvent source, and a steam source. However, in alternative embodiments, there may be more or less sources depending on the process to be selected to remove the flux material 114 between the die 108 and the substrate 110 or the processes to be carried out utilizing the flowhead 200.

In at least another alternative embodiment of the third step 606, a UPW in a liquid state, a gaseous state (i.e., steam UPW), or a semi-gaseous state (i.e., liquid UPW and steam UPW) is ejected from the fluid pathway 214 of the flowhead 200 for a first period of time into the region 106 (i.e., the gap or space) to facilitate removal of the flux material 114, and to facilitate removal of any remaining solvent and flux residue left behind by a previous solvent introduction step if previously performed. After the UPW has been ejected from the fluid pathway 214 of the flowhead 200 for the first period of time into the region 106, a CDA is then ejected from the fluid pathway 214 of the flowhead 200 for a second period of time into the region 106 to facilitate removal of the flux material 114, removal of any remaining solvent and flux residue left behind by a previous solvent introduction step if previously performed, and any remaining UPW. In some embodiments, the first period of time is different from the second period of time, and, in some embodiments, the first period of time is the same as the second period of time. This process of introducing a UPW followed by CDA may be referred to as a cleanse cycle. This cleanse cycle of introducing UPW for the first period of time followed by introducing CDA into the region 106 through the flowhead 200 for the second period of time can be repeated multiple times to further facilitate the removal of the flux material 114, and to facilitate removal of any remaining solvent and flux residue left behind by a previous solvent introduction step if previously performed. For example, this cleanse cycle of switching back and forth between the introduction of UPW and CDA into the region 106 by ejecting the UPW and CDA successively and repetitively from the flowhead 200 can be performed a selected number of times suitable to facilitate removal of the flux material 114, and to facilitate removal of any solvent and flux residue left behind by a previous solvent introduction step if previously performed. For example, in at least one embodiment, the cleanse cycle can be performed up to thirty (30) times, or some other suitable number of times.

In at least one embodiment, the first period of time is equal to 8 seconds(s) and the second period of time is equal to 2 seconds(s). However, in alternative embodiments, the first period of time and the second period of time are selected to further facilitate removal of the flux material 114 within the region 106 and to further facilitate removal of any remaining solvent and flux residue that remains if a solvent was previously introduced into the region 106, for example, through the flowhead 200. Furthermore, in other alternative embodiments, various fluids can be introduced successively in various orders to further facilitate removal of the solvent and flux material within the region 106.

After the third step 606 in which the one or more fluids are ejected from the flowhead 200 to remove the flux material 114 from the region 106 between the die 108 and the substrate 110, in a fourth step 608 the flowhead 200 is removed from the surface 112 of the substrate 110 and the workpiece (i.e., the die 108 coupled to the substrate 110) is picked up and removed from the surface 304 of the support 306. For example, the workpiece is removed from the surface 304 of the support 306 by a pick and place machine, a transfer robot arm (TRA), or by some other suitable or like structure for picking up and removing the workpiece from the surface 304 of the support 306.

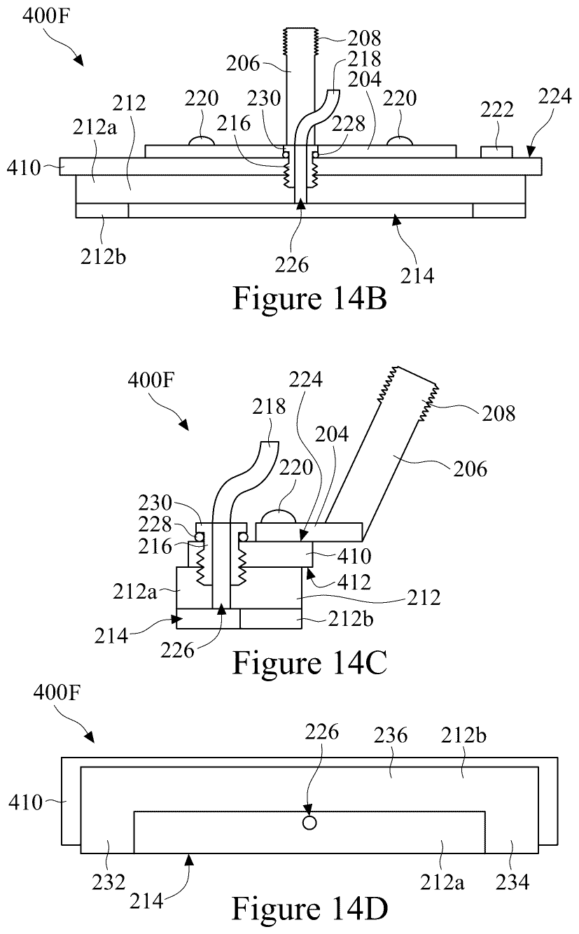

In view of the discussion above, after the flowhead 200 is positioned as shown in FIG. 12, any number of the one or more fluids (i.e., solvent, CDA, UPW, steam, or any other suitable type of fluid in a liquid, gaseous, or semi-gaseous state) is ejected from the flowhead 200 into the region 106 to remove the flux material 114 within the region 106 between the die 108 and the substrate 110. The process is sped up in removing the flux material 114 as the flowhead 200 once positioned does not have to be reoriented. Furthermore, the process is sped up as there is no need for the cover 120 to hold the substrate 110 in place. Instead, the flowhead 200 combines the functionality of the nozzle 102 and the cover 120 into a single component resulting in only having to position the flowhead 200 instead of having to position both the cover 120 and the nozzle 102. All of these reductions in the number of positioning steps results in the process of removing the flux material 114 being significantly sped up. It will be readily appreciated that the above discussion with respect to the method as discussed with respect to the flowchart 600 as shown in FIG. 11 and as discussed with respect to FIG. 12 also readily applies to the alternative embodiment of the flowhead 400F as discussed as follows herein with respect to FIGS. 14A-14D.

FIG. 14A is a perspective view of a flowhead 400F, in accordance with some embodiments. The alternative embodiment of the flowhead 400F is the same or similar to the embodiment of the flowhead 200 as discussed in detail earlier herein with respect to FIGS. 2A-2D of the present disclosure. FIG. 14B is a cross-sectional side view of the flowhead 400F taken along line F-F as shown in FIG. 14A, in accordance with some embodiments. FIG. 14C is a cross-sectional side view of the flowhead 400F taken along line G-G as shown in FIG. 14A, in accordance with some embodiments. FIG. 14D is a bottom side view of the flowhead 400F as shown in FIG. 14A, in accordance with some embodiments.

The alternative embodiment of the flowhead 400F has several of the same or similar features of the embodiment of the flowhead 200, and, therefore, these same or similar features have been provided with the same or similar reference numerals. As these same or similar features were discussed in detail with respect to the embodiment of the flowhead 200 and for the sake of brevity and simplicity of the present disclosure, the following discussion with respect to the alternative embodiment of the flowhead 400F will focus on different or additional features relative to the embodiment of the flowhead 200.

Unlike the embodiment of the flowhead 200 that includes the gasket plate 210 that includes the cavity that receives the gasket 212 such that the gasket 212 is coupled to the gasket plate 210, a gasket plate 410 of the alternative embodiment of the flowhead 400F does not include a cavity to receive the gasket 212. Instead, the gasket 212 is coupled to or held in place on a surface 412 that is opposite to the surface 224 of the gasket plate 410. For example, in at least one version of the alternative embodiment of the flowhead 400F, the gasket 212 is adhered to the surface 412 of the gasket plate 410 by an adhesive (not shown). For example, in at least one other version of the alternative embodiment of the flowhead 400F, the gasket 212 is held in place on the surface 412 of the gasket plate 410 merely by the gasket 212 being inserted onto and receiving the fluid line fitting 216.

In other words, the alternative embodiment of the flowhead 400F is the same or similar to the embodiment of the flowhead 200, but, unlike the embodiment of the flowhead 200 that includes the gasket plate 210, the alternative embodiment of the flowhead 400F includes the gasket plate 410, which is a flat plate. As the gasket plate 410 is the flat plate without the cavity to receive the gasket 212, the gasket plate 410 does not include respective sidewall portions similar to respective sidewall portions of the gasket plate 210 with the cavity for receiving the gasket 212 of the embodiment of the flowhead 200. Otherwise, the alternative embodiment of the flowhead 400F is the same or similar to the embodiment of the flowhead 200 of the present disclosure.

At least one embodiment of a flowhead of the present disclosure is summarized as including: a gasket plate; a gasket on the gasket plate, the gasket including: a first gasket portion; and a second gasket portion, the second gasket portion is coupled to the first gasket portion; a fluid hole extending through the gasket plate and into and through the first gasket portion; a fluid pathway defined and delimited by the first gasket portion and the second gasket portion, the fluid pathway extends into the second gasket portion to the first gasket portion; and a fluid line in fluid communication with the fluid hole, the fluid line is configured, in operation, introduce one or more fluids into the fluid hole.

At least one embodiment of a system is summarized as including: a flowhead including: a gasket plate; a gasket positioned on the gasket plate, the gasket including: a first gasket portion of a first material; and a second gasket portion of a second material, the second gasket portion is coupled to the first gasket portion; a fluid hole extending through the gasket plate and into and through the first gasket portion; a fluid pathway defined and delimited by the first gasket portion and the second gasket portion, the fluid pathway extends into the second gasket portion to the first gasket portion; a fluid line in fluid communication with the fluid hole, the fluid line is configured to, in operation, introduce one or more fluids into the fluid hole; and a mounting protrusion coupled to the gasket plate; a transfer structure including an end effector coupled to the mounting protrusion, the transfer structure is configured to, in operation, move the end effector between one or more locations; a fluid source system in fluid communication with the fluid line through one or more valves in fluid communication with one or more fluid sources of the fluid source system; and a workpiece support configured to, in operation, support a workpiece to be processed.

At least one embodiment of a method of the present disclosure is summarized as including: positioning a workpiece on a surface of a support; positioning a flowhead to be on and abut a surface of the workpiece; introducing one or more fluids through the flowhead into a region between a die and a substrate of the workpiece to remove a flux material present within the region between the die and the substrate; removing the flowhead from the surface of the workpiece; and removing the workpiece from the surface of the support.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flowhead, comprising:
a gasket plate;
a gasket on the gasket plate, the gasket including:
a first gasket portion; and
a second gasket portion, the second gasket portion is coupled to the first gasket portion;
a fluid hole extending through the gasket plate and into and through the first gasket portion;
a fluid pathway defined and delimited by the first gasket portion and the second gasket portion, the fluid pathway extends into the second gasket portion to the first gasket portion; and
a fluid line in fluid communication with the fluid hole, the fluid line is configured, in operation, introduce one or more fluids into the fluid hole.

2. The flowhead of claim 1, further comprising a vibration unit coupled to the gasket plate.

3. The flowhead of claim 2, wherein the vibration unit is configured to, in operation, vibrate the gasket plate and the gasket.

4. The flowhead of claim 1, wherein a first composition of a first material of the first gasket portion is different from a second composition of a second material of the second gasket portion.

5. The flowhead of claim 1, wherein a first composition of a first material of the first gasket portion is the same as a second composition of a second material of the second gasket portion.

6. The flowhead of claim 1, further comprising a mounting protrusion coupled to the gasket plate, the mounting protrusion configured to, in operation, be utilized to mount the gasket plate to an end effector of a transfer structure.

7. The flowhead of claim 6, wherein the transfer structure is a transfer robot arm (TRA).

8. The flowhead of claim 1, wherein the second gasket portion has a U-shape.

9. The flowhead of claim 1, wherein the fluid line is coupled to the fluid hole by a quick release fluid line fitting.

10. The flowhead of claim 1, wherein the second gasket portion of the gasket includes a plurality of channels, and each respective channel of the plurality of channels is separate and distinct from each other.

11. The flowhead of claim 1, wherein the second gasket portion includes a single, continuous channel.

12. A system, comprising:
a flowhead including:
a gasket plate;
a gasket positioned on the gasket plate, the gasket including:
a first gasket portion of a first material; and
a second gasket portion of a second material, the second gasket portion is coupled to the first gasket portion;
a fluid hole extending through the gasket plate and into and through the first gasket portion;
a fluid pathway defined and delimited by the first gasket portion and the second gasket portion, the fluid pathway extends into the second gasket portion to the first gasket portion;
a fluid line in fluid communication with the fluid hole, the fluid line is configured to, in operation, introduce one or more fluids into the fluid hole; and
a mounting protrusion coupled to the gasket plate;
a transfer structure including an end effector coupled to the mounting protrusion, the transfer structure is configured to, in operation, move the end effector between one or more locations;
a fluid source system in fluid communication with the fluid line through one or more valves in fluid communication with one or more fluid sources of the fluid source system; and
a workpiece support configured to, in operation, support a workpiece to be processed.

13. The system of claim 12, wherein the one or more fluid sources of the fluid source system includes at least one of a steam source, a clean dry air (CDA) source, an ultra-pure water (UPW) source, or a solvent source.

14. The system of claim 12, wherein the flowhead further includes a first vibration unit on the gasket plate configured to, in operation, vibrate the gasket plate and the gasket.

15. The system of claim 14, further comprising a second vibration unit on the workpiece support configured to, in operation, vibrate the workpiece support.

16. A method, comprising:
positioning a workpiece on a surface of a support;
positioning a flowhead to be on and abut a surface of the workpiece;
introducing one or more fluids through the flowhead into a region between a die and a substrate of the workpiece to remove a flux material present within the region between the die and the substrate;
removing the flowhead from the surface of the workpiece; and
removing the workpiece from the surface of the support.

17. The method of claim 16, wherein positioning the flowhead to be on and abut the surface of the workpiece further includes clamping the workpiece between the flowhead and the surface of the support.

18. The method of claim 17, wherein clamping the workpiece between the flowhead and the surface of the support further includes abutting and contacting a surface of the substrate with a gasket of the flowhead.

19. The method of claim 16, wherein positioning the flowhead on the surface of the workpiece further includes abutting and contacting the workpiece with a gasket of the flowhead.

20. The method of claim 19, wherein abutting and contacting the workpiece with the gasket of the flowhead forms a seal between the gasket and the workpiece.
